(19) United States
(12) Patent Application Publication
(10) Pub. No.: US 2004/0145066 A1
(43) Pub. Date: Jul. 29, 2004

(54) Laser alignment structure for integrated circuits

(76) Inventors: Leland S. Swanson, McKinney, TX (US); Gregory E. Howard, Dallas, TX (US)

Correspondence Address: TEXAS INSTRUMENTS INCORPORATED, P O BOX 655474, M/S 3999, DALLAS, TX, 75265

(21) Appl. No.: 10/351,112

(22) Filed: Jan. 24, 2003

(51) Int. Cl. H01L 21/76; H01L 23/544

(52) U.S. Cl. 257/797; 438/401

(57) ABSTRACT

Laser alignment structures are formed over an integrated circuit by forming structures of a first width (90) adjacent to structures of a second width (100) where the second width is greater than five times the first width. In addition the structures of a first width are separated from each other by a distance that between one and five times the first width.

### FIELD OF THE INVENTION

This invention relates generally to the field of integrated circuit manufacturing and more particularly to a structure for aligning a laser to features on an integrated circuit.

### BACKGROUND OF THE INVENTION

It is often necessary to form precision capacitors and resistors on integrated circuits with values that can be adjusted after circuit manufacture and during electrical testing of the circuit. The absolute value of these resistors and capacitors is determined by the size of the structures and one commonly used method to adjust the value of these devices is to physically trim the size of the structure using a laser. The effective size of structures can also be modified by cutting out parallel or series segments connected by fusable links. The laser trimming or fuse cutting process requires aligning the laser to the desired structure on the integrated circuit and then physically adjusting the size of the resistor and capacitor by cutting through the device with the laser.

Alignment of a laser to a particular device on an integrated circuit requires the use of alignment structures on the surface of the integrated circuit. Laser alignment structures require a minimum amount of contrast between a background field area and a second alignment geometry of fixed size and shape. Typically the background is made darker than the alignment geometry. Most integrated circuit technologies have a lot of topology in the various layers that will reduce the backscatter reflection of a laser beam that is incident on the surface of the integrated circuit. In these cases the background field adjacent to the second alignment geometry can be darkened by a judicious choice of the various polysilicon and metal layers that comprise the integrated circuit. In this case however the alignment structure will tend to be process dependent and each one has to be tested due to the different layer thicknesses and minimum geometries in each technology.

In integrated circuits where chemical mechanical polishing is used to reduce the surface topology of each layer there is often not enough topology inherent in the manufacture of the integrated circuit that can be used to produce dark fields. For these integrated circuits an opening is often made in the top dielectric layer of the integrated circuit and the laser is aligned using features in the underlying exposed metal layer. The opening is required because the reflectance of the top dielectric layer over the underlying dielectric layer and the underlying metal layer is too similar to produce the required contrast. A major disadvantage of forming the required opening is that contaminants and moisture can enter the integrated circuit through the opening in the top dielectric layer and possibly destroy various electronic devices that are situated close to the opening. There is therefore a need for a laser alignment structure that does not require an opening to be formed in the top dielectric layer and that is suitable for use in integrated circuits where chemical mechanical polishing is used to reduce surface topology.

### SUMMARY OF THE INVENTION

The instant invention is a laser alignment structure for aligning a laser to various structures on an integrated circuit. Spaced structures of a width W_{D} and spacing W_{S} are formed above a semiconductor. The spacing W_{S} is between one to five times the width W_{D} and the structures can be formed using various shapes. A second structure of width W_{B} is formed adjacent to the spaced structures where the width W_{B} is greater than five times the width W_{D}. A dielectric layer is formed over the spaced structure and the second structure. When laser light is incident on the laser alignment structure and the reflected laser light detected, the spaced structures will appear dark and the second structure will appear bright. This allows the laser to detect the position of the alignment structure on the integrated circuit.

### BRIEF DESCRIPTION OF THE DRAWINGS

For a more complete understanding of the present invention and the advantages thereof, reference is now made to the following description taken in conjunction with the accompanying drawings, wherein like reference numerals represent like features, in which:

FIG. 1 is a laser alignment structure on an integrated circuit according to an embodiment of the instant invention.

FIG. 2 is a cross section of a laser alignment structure according to an embodiment of the instant invention.

FIG. 3 is a cross section drawing of a further embodiment of the instant invention.

FIG. 4 is a cross section drawing of a further embodiment of the instant invention.

### DETAILED DESCRIPTION OF THE INVENTION

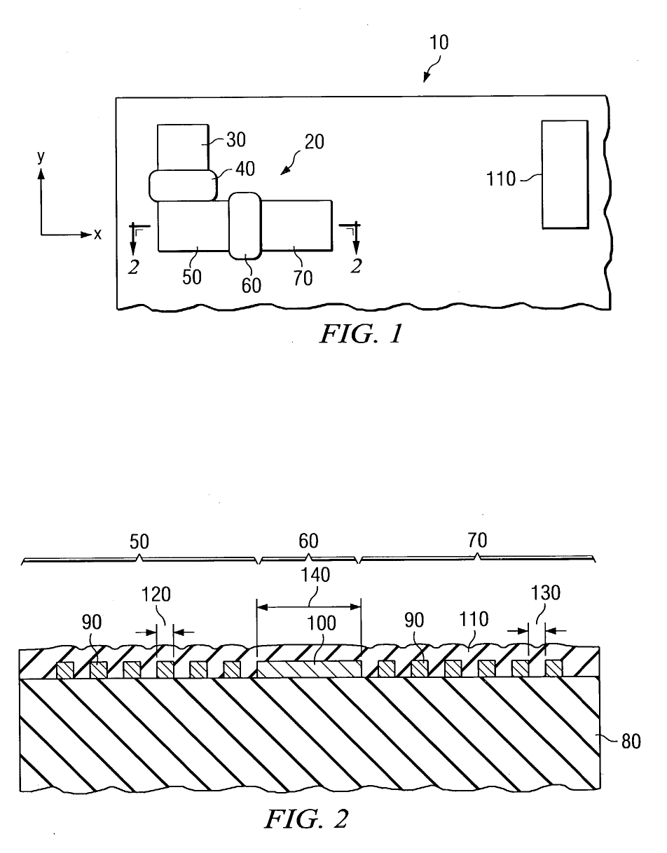

FIGS. 1 and 2 illustrate a laser alignment structure according to an embodiment of the instant invention.

Shown in FIG. 1 is a laser alignment structure 20 formed in a region of an integrated circuit 10. The alignment structure comprises dark regions 70, 50, and 30 adjacent to bright structures 60 and 40. In this disclosure the term dark region refers to a structure that does not reflect (or has significantly reduced reflection of) the incident laser light. The bright structures 40 and 60 are structures that reflect a significant amount of the incident laser light. In operation the position of the alignment structure 20 on the integrated circuit 10 is determined by scanning the laser along the X and Y directions shown in FIG. 1. A photo detector positioned above the integrated circuit 10 will detect the amount of incident laser light that is reflected from the surface of the integrated circuit. As the laser light is scanned across the alignment structure 20 the photo detector will detect the dark regions 30, 50, and 70 adjacent to the bright structures 40 and 60 and the position of the alignment structure 20 on the integrated circuit 10 can be determined. The positions of the electronic structures to be trimmed by the laser are positioned at known coordinates in relation to the position of the alignment structure 20 on the integrated circuit 10. Shown in FIG. 1 is an example of electronic structure 110 that is positioned at a known distance from the alignment structure 20. For the embodiment shown in FIG. 1, once the position of the alignment structure 20 is determined the laser can then be moved or positioned over the electronic structure 110 which can then be trimmed.

Shown in FIG. 2 is a cross section of the alignment structure shown in FIG. 1 taken along the XX′ axis. The cross section shows dark regions 50 and 70 positioned adjacent to a bright region 60. According to an embodiment of the instant invention forming spaced metal structures 90 on the surface of a dielectric layer 80 forms the dark regions 50 and 70. The dielectric layer 80 is formed over various other metal and dielectric layers that are not shown for clarity. In forming the spaced metal structures 90, two dimensions are defined; the width of the structure W_{D} 120 and the spacing between structures W_{S} 130. It should be noted that the width W_{D} is defined in a general sense. If the spaced metal structures are approximately circular in shape, then the dimension defined as the width W_{D} would be equivalent to the diameter of the approximate circular shape. If the spaced metal structures are arbitrarily shaped structures then the width would represent that distance seen on a cross-section of the shape. In general the spacing between the spaced metal structures W_{S} 130 should be between one to five times the width of the spaced metal structure W_{D} 120. In an embodiment of the instant invention the width of the spaced metal structure W_{D} 120 is between 0.75 μm to 1.25 μm. The shape of the spaced metal structures 90 can comprise squares, circles, rectangles, trapezoids, or any shape suitable for formation on an integrated circuit.

In forming the bright structure 60, a metal structure 100 is formed on the surface of the dielectric layer 80. The width W_{B} 140 of the metal structure 100 is large compared to the width of the spaced metal structures W_{D}. In an embodiment, the width of the metal structure W_{B} is greater than five times the width of the spaced metal structure W_{D}. Following the formation of the spaced metal structures 90 and the metal structure 100, a top dielectric layer 110 is formed. The top dielectric layer is a conformal film with a thickness on the order of the width of the spaced metal structures W_{D}. In an embodiment of he instant invention, the top dielectric layer is formed using silicon nitride, silicon carbide or any other suitable dielectric material. As shown in FIG. 2, forming the top dielectric layer over the spaced metal structures 90 and the metal structure 100 results in an undulating surface of the top dielectric layer 110 in the dark regions 50 and 70 and a relatively smooth surface in the bright region 60. The undulations in the surface of the top dielectric layer 110 in the dark regions cause refraction and scattering of the incident laser light and reduces the amount of the incident light that is detected by the photo detector. This results in the regions 50 and 70 appearing dark to the photo detector. The relatively smooth surface on the top dielectric layer 110 in the bright region 60 does not scatter the laser light away from the detector and the region 60 appears bright to the photo detector.

In the above described embodiment of the instant invention the structures 90 and 100 where formed using a metal. In other embodiments of the instant invention other materials can be used to form the structures 90 and 100. These materials include silicon, silicides formed using tungsten, titanium, and cobalt, as well as dielectrics similar too or different from the dielectric material used to form the underlying dielectric layer 80. In addition the invention should not be confined to the shape of the alignment structure 20 shown in FIG. 1. The instant invention can be used to form dark regions and bright regions in any shape or arrangement on the integrated circuit. Rearranging the position of the spaced structures and the bright structure can form other shapes and layouts of the various dark and bright regions on the integrated circuit.

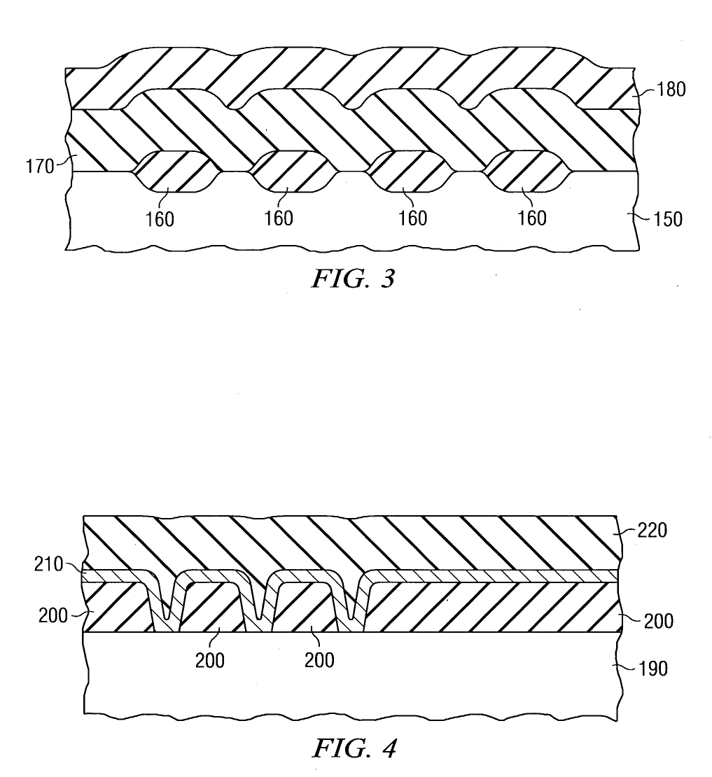

Shown in FIG. 3 is a further embodiment of the instant invention. Field oxide isolation structures 160 are formed in a semiconductor substrate 150. The field oxide isolation structures are patterned so that following the formation of a PMD layer 170 and subsequent layers 180 undulations are formed in the upper surface of the subsequent layers. The regions containing the undulations will appear dark when the structure shown in FIG. 3 is used as part of a laser alignment structure. These structures can be used to form the dark regions of laser alignment structures. The subsequent layers can comprise dielectric, metal, and insulator layers and is not limited to a single layer but includes a plurality of layers or the same or differing material.

Shown in FIG. 4 is a further embodiment of the instant invention. Layer 190 is a layer formed over a semiconductor and comprises a metal layer, a dielectric layer, or any other suitable layer. An ILD layer 200 is formed over layer 190 and openings are formed in the ILD layer 200. A metal layer 210 is formed over the ILD layer 200 and into the openings formed in the ILD layer as shown in FIG. 4. A dielectric layer 220 is formed over the metal layer 210 resulting in the formation of undulations in the surface of the dielectric layer. Other layers can then be formed on the surface of the dielectric layer 220. The regions containing the undulations will appear dark when the above-described structure in FIG. 4 is used as part of a laser alignment structure. These structures can be used to form the dark regions of laser alignment structures.

While this invention has been described with reference to illustrative embodiments, this description is not intended to be construed in a limiting sense. Various modifications and combinations of the illustrative embodiments, as well as other embodiments of the invention will be apparent to persons skilled in the art upon reference to the description. It is therefore intended that the appended claims encompass any such modifications or embodiments.

We claim:

1. An integrated circuit laser alignment structure, comprising:
a dielectric layer;
a plurality of first structures of a first width on said dielectric layer wherein said structures are separated from each other by a first distance; and
at least one second structure of a second width on said dielectric layer adjacent to said plurality of first structures wherein said second width is greater than five times said first width.

2. The integrated circuit alignment structure of claim 1 wherein said first distance is between one to five times said first width.

3. The integrated circuit alignment structure of claim 2 further comprising a second dielectric layer over said first dielectric layer and said first and second structures.

4. The integrated circuit alignment structure of claim 1 wherein said first structures are formed from a material selected from the group consisting of metals, silicon, silicide, and dielectrics.

5. An integrated circuit laser alignment structure, comprising:
a dielectric layer;
a plurality of first structures of a first width on said dielectric layer wherein said structures are separated from each other by a first distance such that said first distance is between one to five times said first width; and
at least one second structure of a second width on said dielectric layer adjacent to said plurality of first structures wherein said second width is greater than five times said first width.

6. The integrated circuit alignment structure of claim 5 further comprising a second dielectric layer over said first dielectric layer and said first and second structures.

7. The integrated circuit alignment structure of claim 5 wherein said first structures are formed from a material selected from the group consisting of metals, silicon, silicide, and dielectrics.

8. An integrated circuit laser alignment structure, comprising:
a dielectric layer;
a plurality of first structures of a first width on said dielectric layer wherein said structures are separated from each other by a first distance;
at least one second structure of a second width on said dielectric layer adjacent to said plurality of first structures wherein said second width is greater than five times said first width; and
a metal layer over said first structures, said second structures, and said dielectric layer.

9. The integrated circuit alignment structure of claim 8 wherein said first distance is between one to five times said first width.

10. The integrated circuit alignment structure of claim 9 further comprising a second dielectric layer over said first dielectric layer and said first and second structures.

11. The integrated circuit alignment structure of claim 8 wherein said first structures are formed with materials selected from the group consisting of silicon and dielectrics.
